(19) United States
(12) Patent Application Publication
(10) Pub. No.: US 2025/0089540 A1
(43) Pub. Date: Mar. 13, 2025

(54) DISPLAY DEVICE, METHOD FOR MANUFACTURING THE SAME, AND ELECTRONIC APPARATUS

(71) Applicant: Sony Semiconductor Solutions Corporation, Kanagawa (JP)

(72) Inventor: Yosuke Motoyama, Kanagawa (JP)

(21) Appl. No.: 18/698,922

(22) PCT Filed: Nov. 14, 2022
(86) PCT No.: PCT/JP22/42249

§ 371 Date: Nov. 18, 2024

(30) Foreign Application Priority Data
Nov. 26, 2021 (JP) 2021-192575

(51) Int. Cl. H10K 59/80; H10K 59/12; H10K 59/35; H10K 59/38

(52) U.S. Cl. CPC H10K 59/879; H10K 59/1201; H10K 59/35; H10K 59/38

(57) ABSTRACT

Provided is a display device capable of improving light extraction efficiency while inhibiting deterioration of characteristics of the display device.

A display device includes a substrate, a plurality of light-emitting elements disposed on the substrate, a multilayer body covering the plurality of light-emitting elements and having a groove around each light-emitting element in plan view, and a resin material provided in the groove. The multilayer body includes a first protective layer, a first metal oxide layer, a second protective layer, and a second metal oxide layer in this order. The groove is provided over the second metal oxide layer and the second protective layer. A refractive index of the resin layer is lower than that of the second protective layer.

### TECHNICAL FIELD

The present disclosure relates to a display device, a method for manufacturing the display device, and an electronic apparatus including the display device.

### BACKGROUND ART

In recent years, organic light-emitting diode (OLED) display devices have been widely used. In an OLED display device, in order to improve light extraction efficiency, a technique of providing reflector structures around light-emitting elements has been proposed (See, for example, Patent Document 1).

### CITATION LIST

### Patent Document

Patent Document 1: Japanese Patent Application Laid-Open No. 2016-45979

### SUMMARY OF THE INVENTION

### Problems to be Solved by the Invention

In an OLED display device provided with reflector structures, however, characteristics of the display device might deteriorate because OLED layers (organic layers including a light-emitting layer) on inclined surfaces of the reflector structures are thinner than OLED layers in light-emitting elements between the reflector structures.

An object of the present disclosure is to provide a display device capable of improving light extraction efficiency while suppressing deterioration of characteristics of the display device, a method for manufacturing the display device, and an electronic apparatus including the display device.

### Solutions to Problems

In order to solve the above problem, a display device according to the present disclosure includes:
a substrate;
a plurality of light-emitting elements disposed on the substrate;
a multilayer body covering the plurality of light-emitting elements and having a groove around each of the light-emitting elements in plan view; and
a resin material provided in the groove, in which
the multilayer body includes a first protective layer, a first metal oxide layer, a second protective layer, and a second metal oxide layer in this order,
the groove is provided over the second metal oxide layer and the second protective layer, and
a refractive index of the resin material is lower than a refractive index of the second protective layer.

An electronic apparatus according to the present disclosure includes the display device according to the present disclosure.

A method for manufacturing a display device includes:
forming a plurality of light-emitting elements on a substrate;
stacking a first protective layer, a first metal oxide layer, a second protective layer, and a second metal oxide layer on the plurality of light-emitting elements in this order;
forming openings in the second metal oxide layer around the light-emitting elements in plan view;
etching the second protective layer using the second metal oxide layer as a mask and forming grooves; and
filling the grooves with a resin material having a refractive index lower than a refractive index of the second protective layer.

### BRIEF DESCRIPTION OF DRAWINGS

FIG. 1 is a schematic diagram illustrating an example of an overall configuration of a display device according to an embodiment.

FIG. 2 is a cross-sectional view illustrating an example of configuration of the display device according to the embodiment.

FIG. 3 is a cross-sectional view obtained by cutting a second protective layer perpendicularly to a thickness direction of the display device.

FIG. 4 is a cross-sectional view illustrating a part of FIG. 2 while enlarging the part.

FIGS. 5A, 5B, and 5C are process diagrams for explaining an example of a method for manufacturing the display device according to the embodiment.

FIG. 6 is a cross-sectional view illustrating an example of configuration of a display device according to a first modification.

FIG. 7 is a cross-sectional view illustrating an example of configuration of a display device according to a second modification.

FIG. 8 is a plan view illustrating an example of a schematic configuration of a module.

FIG. 9A is a front view illustrating an example of an external appearance of a digital still camera. FIG. 9B is a rear view illustrating the example of the external appearance of the digital still camera.

FIG. 10 is a perspective view illustrating an example of an external appearance of a head-mounted display.

FIG. 11 is a perspective view illustrating an example of an external appearance of a television apparatus.

FIG. 12 is a cross-sectional view illustrating a model of a display device used in simulation 1.

FIG. 13 is a cross-sectional view illustrating a model of a display device used in simulation 2.

FIG. 14 is a graph showing results of the simulations.

### MODE FOR CARRYING OUT THE INVENTION

An embodiment and application examples of the present disclosure will be described in the following order. Note that the same or corresponding elements will be denoted by the same reference signs in all the drawings for the following embodiment.
1 Embodiment (Example of Display Device)
2 Modifications (Modifications of Display Device)
3 Application Example (Example of Electronic Apparatus)
4 Simulations

### 1 Embodiment

### [Configuration of Display Device 10]

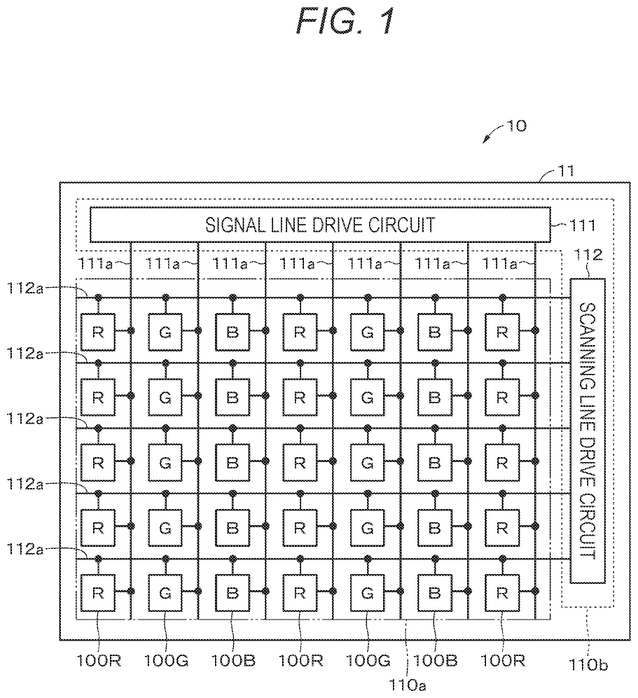

FIG. 1 is a schematic diagram illustrating an example of an overall configuration of a display device 10 according to an embodiment. The display device 10 is an OLED display device and includes a display region 110a and a peripheral region 110b provided on the periphery of the display region 110a. In the display region 110a, a plurality of sub-pixels 100R, 100G, and 100B is provided in two dimensions in a particular arrangement pattern such as a delta or a matrix. Note that FIG. 1 illustrates an example where the plurality of sub-pixels 100R, 100G, and 100B is arranged in two dimensions in a matrix.

The sub-pixels 100R can display red. The sub-pixels 100G can display green. The sub-pixels 100B can display blue. Red is an example of a first primary color among three primary colors. Green is an example of a second primary color among the three primary colors. Blue is an example of a third primary color among the three primary colors. Note that, in the following description, in a case where the sub-pixels 100R, 100G, and 100B are collectively referred to without being particularly distinguished from one another, the sub-pixels 100R, 100G, and 100B will be referred to as sub-pixels 100. A combination of adjacent sub-pixels 100R, 100G, and 100B constitutes one pixel (pixel). FIG. 1 illustrates an example where a combination of the three sub-pixels 100R, 100G, and 100B arranged in a row direction (horizontal direction) constitutes one pixel, but the arrangement of the sub-pixels 100R, 100G, and 100B is not limited to this. The sub-pixels 100R, 100G, and 100B have, for example, a quadrangular shape such as a rectangular shape in plan view. In the present specification, the rectangular shape includes a square shape. In the present specification, a plan view refers to a plan view at a time when an object is viewed from a direction perpendicular to a display surface of the display device 10.

In the peripheral region 110b, a signal line drive circuit 111 and a scanning line drive circuit 112, which are drivers for video display, are provided. The signal line drive circuit 111 supplies a signal voltage of a video signal corresponding to luminance information supplied from a signal supply source (not illustrated) to sub-pixels 100 selected via signal lines 111a. The scanning line drive circuit 112 includes a shift register or the like that sequentially shifts (transfers) a start pulse in synchronization with an input clock pulse. The scanning line drive circuit 112 scans the sub-pixels 100 row by row at a time of writing a video signal to the sub-pixels 100, and sequentially supplies a scanning signal to scanning lines 112a.

The display device 10 is an example of a light-emitting device. The display device 10 is a top-emission type OLED display device. The display device 10 may be a microdisplay. The display device 10 may be provided in a virtual reality (VR) apparatus, a mixed reality (MR) apparatus, an augmented reality (AR) apparatus, an electronic viewfinder (EVF), a small projector, or the like.

In the following description, in each layer constituting the display device 10, a surface on a top side (display surface side) of the display device 10 will be referred to as a first surface, and a surface on a bottom side (a surface opposite the display surface) of the display device 10 will be referred to as a second surface.

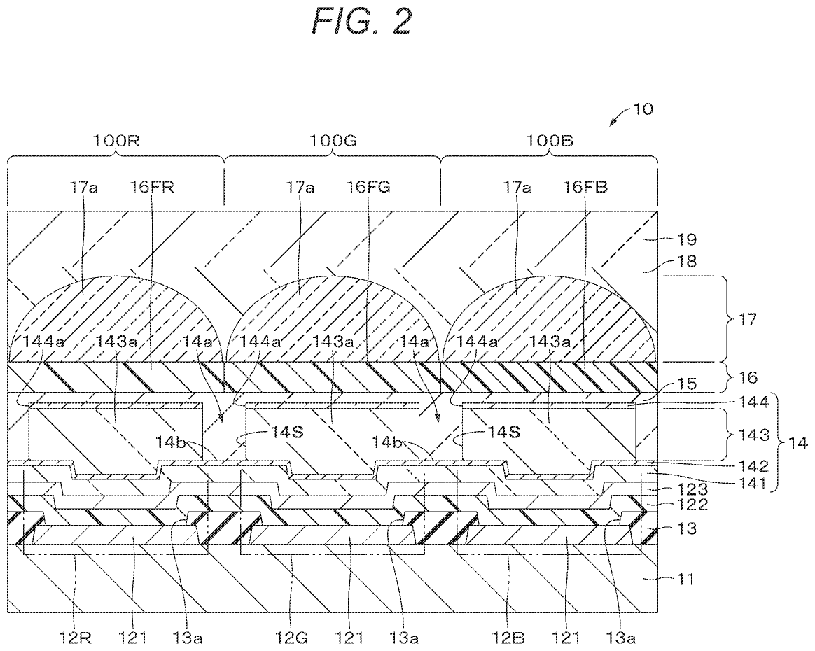

FIG. 2 is a cross-sectional view illustrating an example of configuration of the display device 10 according to the embodiment. The display device 10 includes a drive substrate 11, a plurality of light-emitting elements 12R, 12G, and 12B, an insulating layer 13, a multilayer body 14, a resin layer 15, a color filter 16, a lens array 17, a filling resin layer 18, and a counter substrate 19. Note that, in the following description, in a case where the light-emitting elements 12R, 12G, and 12B are collectively referred to without being particularly distinguished from one another, the light-emitting elements 12R, 12G, and 12B will be referred to as light-emitting elements 12.

### (Drive Substrate 11)

The drive substrate 11 is a so-called backplane, and drives the plurality of light-emitting elements 12. The drive substrate 11 is provided with a drive circuit that drives the plurality of light-emitting elements 12, a power supply circuit that supplies power to the plurality of light-emitting elements 12, and the like (none of which is illustrated).

A substrate body of the drive substrate 11 may be formed by, for example, a semiconductor that can be easily formed, such as a transistor, or may be formed by glass or a resin having low moisture and oxygen permeability. Specifically, the substrate body may be a semiconductor substrate, a glass substrate, a resin substrate, or the like. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

### (Light-Emitting Elements 12R, 12G, and 12B)

The light-emitting elements 12R are included in the sub-pixels 100R. The light-emitting elements 12G are included in the sub-pixels 100G. The light-emitting elements 12B are included in the sub-pixels 100B. The light-emitting elements 12R, 12G, and 12B have the same configuration. The light-emitting elements 12 are white OLED elements, and can emit white light under control of the drive circuit or the like. The white OLED element may be a white micro-OLED (MOLED) element. A method where a white OLED element and the color filter 16 are combined together is used as a coloring method in the display device 10 according to the present embodiment, but the coloring method is not limited thereto.

The plurality of light-emitting elements 12 is arranged in two dimensions on the first surface of the drive substrate 11 in a particular arrangement pattern such as a delta or a matrix. The plurality of light-emitting elements 12 includes a plurality of first electrodes 121, an OLED layer 122, and a second electrode 123 in this order on the first surface of the drive substrate 11.

### (First Electrodes 121)

The plurality of first electrodes 121 is arranged in two dimensions on the first surface of the drive substrate 11 in an arrangement pattern similar to that of the plurality of sub-pixels 100. The first electrodes 121 are anodes. When a voltage is applied between the first electrodes 121 and the second electrode 123, holes are injected into the OLED layer 122 from the first electrodes 121. The first electrodes 121 are separately provided for the plurality of sub-pixels 100.

The first electrodes 121 may be achieved by, for example, a metal layer, or may be achieved by a metal layer and a transparent conductive oxide layer. In a case where the first electrodes 121 are achieved by a metal layer and a transparent conductive oxide layer, the transparent conductive oxide layer is preferably provided on an OLED layer 122 side from a viewpoint of disposing a layer having a high work function adjacent to the OLED layer 122.

The metal layer also has a function as a reflective layer that reflects light generated in the OLED layer 122. The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

A base layer (not illustrated) may be provided adjacent to a second surface side of the metal layer. The base layer is for improving crystal orientation of the metal layer at a time of forming the metal layer. The base layer includes, for example, at least one metal element selected from a group including titanium (Ti) and tantalum (Ta). The base layer may include the at least one metal element described above as a constituent element of an alloy.

The transparent conductive oxide layer includes a transparent conductive oxide. The transparent conductive oxide includes, for example, at least one selected from a group including a transparent conductive oxide including indium (hereinafter referred to as an “indium-based transparent conductive oxide”), a transparent conductive oxide including tin (hereinafter referred to as a “tin-based transparent conductive oxide”), and a transparent conductive oxide including zinc (hereinafter referred to as a “zinc-based transparent conductive oxide”).

The indium-based transparent conductive oxide includes, for example, indium tin oxide (ITO), indium zinc oxide (IZO), indium gallium oxide (IGO), or indium gallium zinc oxide (IGZO) fluorine-doped indium oxide (IFO). Among these transparent conductive oxides, indium tin oxide (ITO) is particularly preferable. This is because indium tin oxide (ITO) has a particularly low barrier for hole injection into the OLED layer 122 in terms of a work function, so that the drive voltage of the display device 10 can be significantly reduced. The tin-based transparent conductive oxide includes, for example, tin oxide, antimony-doped tin oxide (ATO), or fluorine-doped tin oxide (FTO). The zinc-based transparent conductive oxide includes, for example, zinc oxide, aluminum-doped zinc oxide (AZO), boron-doped zinc oxide, or gallium-doped zinc oxide (GZO).

A lower limit value of width of the first electrodes 121 is preferably 1 μm or larger, and more preferably 5 μm or larger, from a viewpoint of improving luminance and a viewing angle. An upper limit value of the width of the first electrodes 121 is preferably 5 μm or smaller, and more preferably 4 μm or smaller, from a viewpoint of improving light focusing efficiency. In the present specification, the width of the first electrodes 121 refers to the width of the first electrodes 121 in a horizontal direction of the display device 10.

### (OLED Layer 122)

The OLED layer 122 is provided between the plurality of first electrodes 121 and the second electrode 123. The OLED layer 122 is continuously provided over the plurality of sub-pixels 100 (that is, the plurality of blue sub-pixels 100B, the plurality of green sub-pixels 100G, and the plurality of red sub-pixels 100R) in the display region 110a and shared by the plurality of sub-pixels 100 in the display region 110a.

The OLED layer 122 is an example of an organic layer including a light-emitting layer. The OLED layer 122 can emit white light. The OLED layer 122 may be an OLED layer including a single-layer light-emitting unit, may be an OLED layer including two layers of light-emitting units (tandem structure), or may be an OLED layer having another structure. The OLED layer having a single-layer light-emitting unit has a configuration in which, for example, a hole injection layer, a hole transport layer, a red-light-emitting layer, a light emission separation layer, a blue-light-emitting layer, a green-light-emitting layer, an electron transport layer, and an electron injection layer are stacked on one another in this order from the first electrodes 121 toward the second electrode 123. The OLED layer including a two-layer light-emitting unit has a configuration in which, for example, a hole injection layer, a hole transport layer, a blue-light-emitting layer, an electron transport layer, a charge generation layer, a hole transport layer, a yellow-light-emitting layer, an electron transport layer, and an electron injection layer are stacked on one another in this order from the first electrodes 121 to the second electrode 123.

The hole injection layer is for enhancing hole injection efficiency of each light-emitting layer and suppressing leakage. The hole transport layer is for enhancing hole transport efficiency of each light-emitting layer. The electron injection layer is for enhancing electron injection efficiency of each light-emitting layer. The electron transport layer is for enhancing electron transport efficiency of each light-emitting layer. The light emission separation layer is a layer for adjusting injection of carriers into each light-emitting layer, and light emission balance of each color is adjusted by injecting electrons or holes into each light-emitting layer via the light emission separation layer. The charge generation layer supplies electrons and holes to two light-emitting layers sandwiching the charge generation layer.

When an electric field is applied to the red-light-emitting layer, the green-light-emitting layer, the blue-light-emitting layer, and the yellow-light-emitting layer, holes injected from the first electrodes 121 or the charge generation layer and electrons injected from the second electrode 123 are recombined together, and red light, green light, blue light, and yellow light are generated, respectively.

### (Second Electrode 123)

The second electrode 123 is a transparent electrode having transparency to visible light. In the present specification, visible light refers to light in a wavelength range of 360 nm or longer and 830 nm. The second electrode 123 is provided in such a way as to face the plurality of first electrodes 121. The second electrode 123 is provided continuously over all the plurality of sub-pixels 100 in the display region 110a and shared by the plurality of sub-pixels 100 in the display region 110a. The second electrode 123 is a cathode. When a voltage is applied between the first electrodes 121 and the second electrode 123, electrons are injected into the OLED layer 122 from the second electrode 123.

The second electrode 123 preferably contains a material having as high transmissivity as possible and a small work function, in order to enhance light emission efficiency. The second electrode 123 is formed by, for example, at least a metal layer or a transparent conductive oxide layer. More specifically, the second electrode 123 is formed by a single-layer film of a metal layer or a transparent conductive oxide layer, or a multilayer film of a metal layer and a transparent conductive oxide layer. In a case where the second electrode 123 is formed by a multilayer film, the metal layer may be provided on the OLED layer 122 side or the transparent conductive oxide layer may be provided on the OLED layer 122 side, but from a viewpoint of disposing a layer having a low work function adjacent to the OLED layer 122, the metal layer is preferably provided on the OLED layer 122 side.

The metal layer includes, for example, at least one metal element selected from a group including magnesium (Mg), aluminum (Al), silver (Ag), calcium (Ca), and sodium (Na). The metal layer may include the at least one metal element described above as a constituent element of an alloy. Specific examples of the alloy include an Mg—Ag alloy, an Mg—Al alloy, an Al—Li alloy, and the like. The transparent conductive oxide layer includes a transparent conductive oxide. As the transparent conductive oxide, a material similar to the transparent conductive oxide of the first electrodes 121 described above can be exemplified.

### (Insulating Layer 13)

The insulating layer 13 is provided on the first surface of the drive substrate 11 between adjacent first electrodes 121. The insulating layer 13 insulates adjacent light-emitting elements 12 from each other. More specifically, the insulating layer 13 insulates adjacent first electrodes 121 from each other. The insulating layer 13 has a plurality of openings 13a. Each of the plurality of openings 13a provided for one of the sub-pixels 100. More specifically, each of the plurality of openings 13a is provided on the first surface (a surface on the OLED layer 122 side) of each first electrode 121. The first electrodes 121 and the OLED layer 122 are in contact with each other through the openings 13a.

The insulating layer 13 may be an organic insulating layer, an inorganic insulating layer, or a multilayer body including these. The organic insulating layer includes, for example, at least one selected from a group including a polyimide-based resin, an acrylic-based resin, a novolac-based resin, and the like. The inorganic insulating layer includes, for example, at least one selected from a group including silicon oxide (SiOₓ), silicon nitride (SiNₓ), silicon oxynitride (SiOₓN_{y}), and the like.

### (Multilayer Body 14)

The multilayer body 14 includes a first protective layer 141, a first metal oxide layer 142, a second protective layer 143, and a second metal oxide layer 144 in this order. The multilayer body 14 has transparency to visible light. The multilayer body 14 shields the light-emitting elements 12 from outside air and inhibits infiltration of moisture into the light-emitting elements 12 from an external environment. Furthermore, in a case where the second electrode 123 includes a metal layer, the multilayer body 14 may have a function of inhibiting oxidation of the metal layer.

The multilayer body 14 is provided on the plurality of light-emitting elements 12 and covers the plurality of light-emitting elements 12. The multilayer body 14 has a groove 14a around each light-emitting element 12 in plan view. The grooves 14a are provided between adjacent light-emitting elements 12 in plan view. The grooves 14a are provided over the second metal oxide layer 144 and the second protective layer 143.

The grooves 14a function as orthogonal crystal waveguides (OCWs) capable of guiding light emitted from the light-emitting elements 12 in an oblique direction with respect to the first surface of the drive substrate 11 to a front surface of the display device 10. The grooves 14a are provided above the insulating layer 13. The grooves 14a are located between the light-emitting elements 12 in plan view. More specifically, the grooves 14a each have a closed loop shape in plan view and surround one of the light-emitting elements 12 in plan view. The grooves 14a are preferably provided outside the openings 13a in the insulating layer 13 in plan view. Since the grooves 14a are provided outside the openings 13a in the insulating layer 13 as described above, emitted light can be efficiently extracted to the front surface.

The grooves 14a have bottoms 14b. The grooves 14a are provided down to a position of the first surface of the first metal oxide layer 142. That is, the bottoms 14b of the grooves 14a are the first metal oxide layer 142. The first protective layer 141 and the first metal oxide layer 142 are provided between the bottoms 14b and the light-emitting elements 12. As a result, when the grooves 14a are formed through etching, etching damage to the light-emitting elements 12 (particularly the OLED layer 122) can be inhibited.

Side surfaces 14S of the grooves 14a may be perpendicular to the first surface of the drive substrate 11 or may be inclined with respect to the first surface of the drive substrate 11. In a case where the side surfaces 14S are inclined, an inclination angle of the side surfaces 14S with respect to the first surface of the drive substrate 11 is, for example, smaller than 90° C. The side surfaces 14S may be curved in a concave shape or may be curved in a convex shape.

A lower limit value of width of the grooves 14a is preferably 0.5 μm or larger. When the width of the grooves 14a is 0.5 μm or greater, light emitted from the OLED layer 122 can be refracted in a front surface direction due to a difference in a refractive index between the grooves 14a (the resin layer 15 in the grooves 14a) and the second protective layer 143, thereby enhancing light focusing properties. An upper limit value of the width of the grooves 14a is, for example, 5 μm or smaller. In a case where the side surfaces 14S of the grooves 14a are inclined or the like and the width of the grooves 14a changes in a depth direction of the grooves 14a, a maximum value of the width of the grooves 14a that changes in the depth direction is defined as the width of the grooves 14a.

A lower limit value of depth of the grooves 14a is preferably 0.5 μm or larger. When the depth of the grooves 14a is 0.5 μm or greater, light emitted from the OLED layer 122 can be refracted in the front surface direction due to the difference in the refractive index between the grooves 14a (the resin layer 15 in the grooves 14a) and the second protective layer 143, thereby enhancing the light focusing properties. An upper limit value of the depth of the grooves 14a is, for example, 5 μm or smaller.

A lower limit value of an aspect ratio of the grooves 14a is preferably 1 or larger. When the aspect ratio of the grooves 14a is 1 or larger, light emitted from the OLED layer 122 can be refracted in the front surface direction due to the difference in the refractive index between the grooves 14a (the resin layer 15 in the grooves 14a) and the second protective layer 143, thereby enhancing the light focusing properties. An upper limit value of the aspect ratio of the grooves 14a is, for example, 5 or smaller. In the present specification, the aspect ratio of the grooves 14a represents a ratio of the depth of the grooves 14a to the width of the grooves 14a (the depth of the grooves 14a/the width of the grooves 14a).

### (First Protective Layer 141 and Second Protective Layer 143)

The first protective layer 141 is provided on the first surface of the second electrode 123 and covers the plurality of light-emitting elements 12. The second protective layer 143 is provided on the first surface of the first metal oxide layer 142.

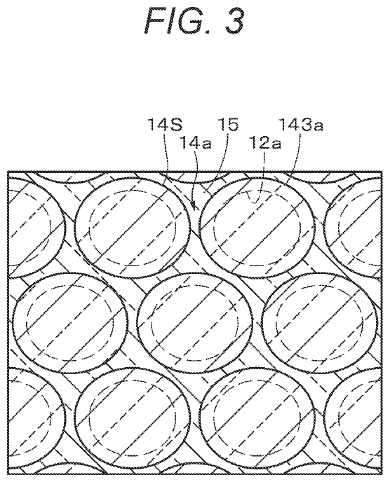

FIG. 3 is a cross-sectional view obtained by cutting the second protective layer 143 perpendicularly to a thickness direction of the display device 10. The second protective layer 143 includes a plurality of structures 143a. The plurality of structures 143a is arranged in two dimensions on the first surface of the first metal oxide layer 142 in a particular arrangement pattern such as a delta or a matrix. The second protective layer 143 has grooves 14a between adjacent structures 143a. Each structure 143a is provided above the light-emitting elements 12. The structures 143a have, for example, a columnar or frustum shape. The columnar structures 143a have side surfaces 14S perpendicular to the first surface of the drive substrate 11. The frustum structures 143a have side surfaces 14S inclined with respect to the first surface of the drive substrate 11. The side surfaces 14S of the frustum structures 143a may be curved in a convex shape or may be curved in a concave shape. In a case where the side surfaces 14S of the frustum structures 143a are curved in a convex shape, the structures 143a can function as convex lenses, so that light emitted from the light-emitting elements 12 can be focused. The columnar shape of the structures 143a is, for example, a round columnar shape, an elliptical columnar shape, or a prismatic shape. A bottom surface of the prismatic shape is, for example, a polygon such as a quadrangle or a hexagon. The elliptic columnar structures 143a are disposed, for example, such that a major axis of a bottom surface of an elliptic column becomes parallel to a horizontal direction of the display surface. The frustum shape of the structures 143a is, for example, a conical frustum shape or a pyramidal frustum shape. A bottom surface of the pyramidal frustum shape is, for example, a polygon such as a quadrangle or a hexagon. The elliptic frustum structures 143a are disposed, for example, such that a major axis of a bottom surface of an elliptic frustum becomes parallel to the horizontal direction of the display surface.

The first protective layer 141 and the second protective layer 143 include, for example, an inorganic material or a polymer resin having low hygroscopicity. The first protective layer 141 and the second protective layer 143 may have a single-layer structure or a multilayer structure. Layer structures of the first protective layer 141 and the second protective layer 143 may be the same or different from each other. In a case where thickness of the first protective layer 141 and the second protective layer 143 is increased, it is preferable to have a multilayer structure. This is for alleviating internal stress in the first protective layer 141 and the second protective layer 143.

A refractive index of the first protective layer 141 is higher than that of the resin layer 15. The refractive index of the first protective layer 141 is, for example, 1.6 or higher and 1.9 or lower. A refractive index of the second protective layer 143 is higher than that of the resin layer 15. The refractive index of the second protective layer 143 is, for example, 1.6 or higher and 1.9 or lower. The refractive index of the first protective layer 141 and the refractive index of the second protective layer 143 may be the same. In the present specification, a refractive index refers to a refractive index with respect to light having a wavelength of 550 nm.

The inorganic material includes, for example, at least one selected from a group including silicon oxide (SiOₓ), silicon nitride (SiNₓ), silicon oxynitride (SiOₓN_{y}), titanium oxide (TiOₓ), aluminum oxide (AlOₓ), and the like. The polymer resin includes, for example, at least one selected from a group including a thermosetting resin, an ultraviolet curable resin, and the like. Materials of the first protective layer 141 and the second protective layer 143 may be the same or different from each other.

### (First Metal Oxide Layer 142 and Second Metal Oxide Layer 144)

Etching rates of the first metal oxide layer 142 and the second metal oxide layer 144 are lower than that of the second protective layer 143. Here, an etching rate refers to the amount of decrease per unit time in thickness of a member to be etched in an etching step. The etching may be either dry etching or wet etching.

The first metal oxide layer 142 may be used as an etching stopper layer that prevents the first protective layer 141 from being etched as the grooves 14a (over-etching) when the grooves 14a are formed through etching.

The first metal oxide layer 142 is provided on the first surface of the first protective layer 141. That is, the first metal oxide layer 142 is provided between the first protective layer 141 and the second protective layer 143. The first metal oxide layer 142 constitutes the bottoms 14b of the grooves 14a.

The first metal oxide layer 142 is preferably a deposited monolayer. When the first metal oxide layer 142 is a deposited monolayer, the etching rate of the first metal oxide layer 142 can be made lower than that of the second protective layer 143. Furthermore, when the first metal oxide layer 142 is a deposited monolayer, an effect of inhibiting infiltration of moisture, the effect being produced by the multilayer body 14, can be improved. The first metal oxide layer 142 includes, for example, aluminum oxide or titanium oxide.

The second metal oxide layer 144 may be used as a mask when the grooves 14a are formed through etching. The second metal oxide layer 144 covers the first surface of the second protective layer 143, that is, upper surfaces of the plurality of structures 143a. The second metal oxide layer 144 has openings 144a. The openings 144a are provided above the insulating layer 13 in plan view and constitute upper-end openings of the grooves 14a.

The second metal oxide layer 144 is preferably a deposited monolayer. When the second metal oxide layer 144 is a deposited monolayer, the etching rate of the second metal oxide layer 144 can be made lower than that of the second protective layer 143. Furthermore, when the second metal oxide layer 144 is a deposited monolayer, the effect of inhibiting infiltration of moisture, the effect being produced by the multilayer body 14, can be improved. The second metal oxide layer 144 includes, for example, aluminum oxide or titanium oxide.

Thickness of the first metal oxide layer 142 and thickness of the second metal oxide layer 144 may be different from each other or the same. In a case where the thickness of the first metal oxide layer 142 is different from that of the second metal oxide layer 144, the second metal oxide layer 144 is preferably thicker than the first metal oxide layer 142. This is because the second metal oxide layer 144 is subjected to etching for a longer time than the first metal oxide layer 142.

### (Resin Layer 15)

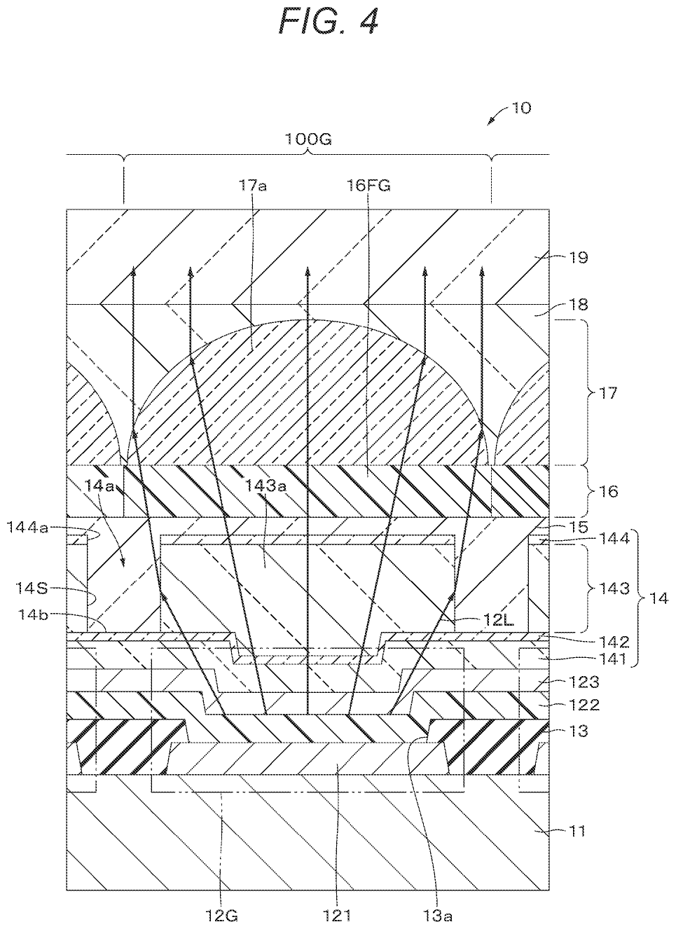

The resin layer 15 has transparency to visible light. The resin layer 15 is a so-called planarization layer, and part of the resin layer 15 is provided in the grooves 14a to fill the grooves 14a, and the rest of the resin layer 15 covers the first surface of the second protective layer 143. A refractive index of the resin layer 15 is lower than that of the second protective layer 143. As a result, as illustrated in FIG. 4, light 12L emitted from each of the light-emitting elements 12R, 12G, and 12B in an oblique direction with respect to the first surface of the drive substrate 11 can be refracted by the side surfaces 14S of the grooves 14a and directed to the front surface of the display device 10. The light 12L emitted from each of the light-emitting elements 12R, 12G, and 12B in an oblique direction with respect to the first surface of the drive substrate 11, therefore, can be guided to the front surface of the display device 10. As a result, light extraction efficiency of the display device 10 can be improved.

The refractive index of the resin layer 15 is, for example, 1.3 or higher and 1.5 or lower. A difference in the refractive index between the second protective layer 143 and the resin layer 15 is preferably 0.1 or larger and 0.5 or smaller, and more preferably 0.2 or larger and 0.5 or smaller. When the difference in the refractive index is 0.1 or larger, an effect of focusing light produced by the grooves 14a can be improved. A difference in the refractive index between the first protective layer 141 and the resin layer 15 is preferably 0.1 or larger and 0.5 or smaller, and more preferably 0.2 or larger and 0.5 or smaller.

Although FIG. 4 illustrates an example in which the light 12L emitted from the light-emitting elements 12 in the oblique direction with respect to the first surface of the drive substrate 11 is refracted by the side surfaces 14S of the grooves 14a, part of the light 12L emitted from the light-emitting elements 12 in the oblique direction with respect to the first surface of the drive substrate 11 may be totally reflected by the side surfaces 14S of the grooves 14a. The light extraction efficiency of the display device 10 can also be improved with such total reflection.

The resin layer 15 includes, for example, at least one selected from a group including a thermosetting resin, an ultraviolet curable resin, and the like. From the viewpoint of filling properties of the resin layer 15 with respect to the grooves 14a, the resin layer 15 preferably contains an ultraviolet curable resin.

### (Color Filter 16)

The color filter 16 is provided above the plurality of light-emitting elements 12. More specifically, the color filter 16 is provided on the first surface of the resin layer 15. The color filter 16 is, for example, an on-chip color filter (OCCF). The color filter 16 includes, for example, a plurality of red filter portions 16FR, a plurality of green filter portions 16FG, and a plurality of blue filter portions 16FB. Note that, in the following description, the red filter portions 16FR, the green filter portions 16FG, and the blue filter portions 16FB will be collectively referred to as filter portions 16F in a case where the red filter portions 16FR, the green filter portions 16FG, and the blue filter portions 16FB are not particularly distinguished from one another.

The plurality of filter portions 16F is arranged in two dimensions in an in-plane direction. In the present description, the in-plane direction refers to an in-plane direction on the first surface of the drive substrate 11. Each filter part 16F is provided above one of the light-emitting elements 12. More specifically, the red filter portions 16FR are provided above the light-emitting elements 12R, the green filter portions 16FG are provided above the light-emitting elements 12G, and the blue filter portions 16FB are provided above the light-emitting elements 12B. The red filter portions 16FR and the light-emitting elements 12R together constitute the sub-pixels 100R, the green filter portions 16FG and the light-emitting elements 12G together constitute the sub-pixels 100G, and the blue filter portions 16FB and the light-emitting elements 12B together constitute the sub-pixels 100B.

The red filter portions 16FR transmit red light out of the white light emitted from the light-emitting elements 12R and absorb light other than the red light. The green filter portions 16FG transmit green light out of the white light emitted from the light-emitting elements 12G and absorb light other than the green light. The blue filter portions 16FB transmit blue light out of the white light emitted from the light-emitting elements 12B and absorb light other than the blue light.

The red filter portions 16FR include, for example, red color resist. The green filter portions 16FG include, for example, green color resist. The blue filter portions 16FB include, for example, blue color resist.

### (Lens Array 17)

The lens array 17 includes a plurality of lenses 17a. The lenses 17a focus light emitted upward from the filter portions 16F. The lenses 17a have, for example, convex curved surfaces protruding toward the display surface. The curved surfaces have, for example, a dome shape, a paraboloid shape, a hemispherical shape, a semi-ellipsoidal shape, or the like. The lenses 17a may be on-chip microlenses (OCLs). The plurality of lenses 17a is arranged in two dimensions on the first surface of the color filter 16 in a particular arrangement pattern such as a delta or a matrix. Each lens 17a is provided above one of the light-emitting elements 12. The lenses 17a are provided on the first surfaces of the filter portions 16F.

As described above, since the display device 10 includes the lens array 17 on the first surface of the color filter 16, the light 12L emitted from the light-emitting elements 12 can be guided to the front surface of the display device 10 by the grooves 14a and can then be further focused by the lenses 17a as illustrated in FIG. 4. Luminance in a front surface direction and light extraction efficiency, therefore, can be further improved.

By adjusting the curved surfaces of the lenses 17a, however, the light 12L emitted from the light-emitting elements 12 may be guided to the front surface of the display device 10 by the grooves 14a and then diffused by the lenses 17a. Such a configuration is effective in a case where the grooves 14a effectively focus light and luminance in an oblique direction decreases.

The periphery of the lenses 17a is preferably located above the grooves 14a. As a result, as illustrated in FIG. 4, the light 12L refracted by the side surfaces 14S of the grooves 14a and emitted upward from the grooves 14a can be focused by edge portions of the lenses 17a. The light 12L, however, may be diffused by the edge portions of the lenses 17a by adjusting the curved surfaces of the lenses 17a.

The lenses 17a contain, for example, an inorganic material or a polymer resin transparent to visible light. The inorganic material includes, for example, silicon oxide (SiOₓ). The polymer resin includes, for example, an ultraviolet curable resin.

### (Filling Resin Layer 18)

The filling resin layer 18 is provided between the lens array 17 and the counter substrate 19. The filling resin layer 18 fills a gap between the lens array 17 and the counter substrate 19 and adheres the lens array 17 and the counter substrate 19. The filling resin layer 18 includes, for example, at least one selected from a group including a thermosetting resin, an ultraviolet curable resin, and the like.

### (Counter Substrate 19)

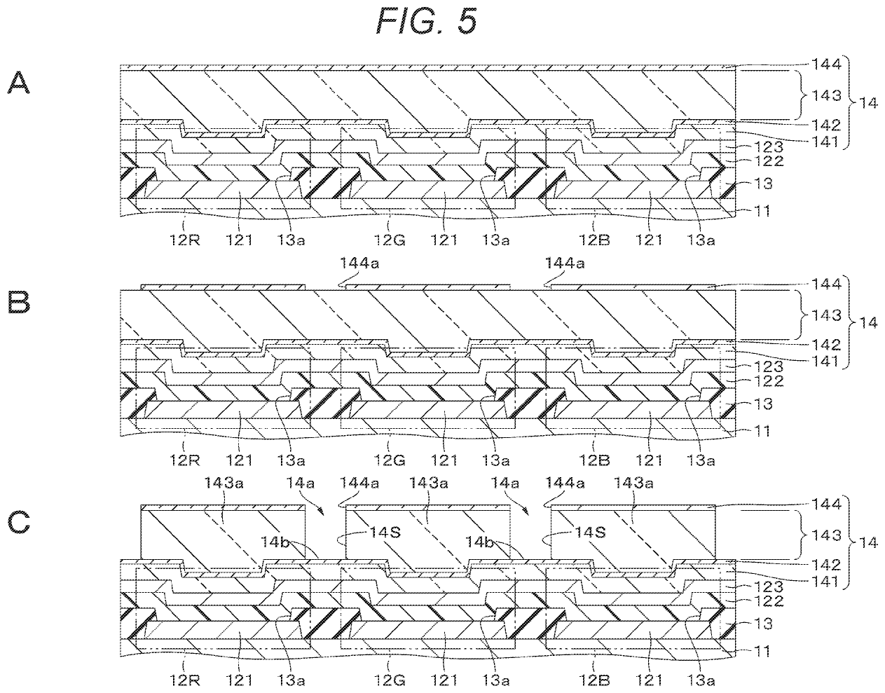

The counter substrate 19 is provided on the first surface of the filling resin layer 18 and faces the drive substrate 11. The counter substrate 19 and the filling resin layer 18 seal the light-emitting element 12, the color filter 16, and the like. The counter substrate 19 includes a material such as glass transparent to each color of light emitted from the color filter 16. [Method for Manufacturing Display Device 10] An example of a method for manufacturing the display device 10 according to an embodiment of the present disclosure will be described hereinafter with reference to FIGS. 5A to 5C.

First, a metal layer and a metal oxide layer are sequentially formed on the first surface of the drive substrate 11 by, for example, a sputtering method, and then the metal layer and the metal oxide layer are patterned using, for example, a photolithography technique and an etching technique. The plurality of first electrodes 121 is thus formed on the first surface of the drive substrate 11.

Next, the insulating layer 13 is formed on the first surface of the drive substrate 11 in such a way as to cover the plurality of first electrodes 121 by, for example, a chemical vapor deposition (CVD) method. Next, the openings 13a are formed in the insulating layer 13 at portions corresponding to the first surfaces of the first electrodes 121 by, for example, a photolithography technique and a dry etching technique.

Next, a hole transport layer, a red-light-emitting layer, a light emission separation layer, a blue-light-emitting layer, a green-light-emitting layer, an electron transport layer, and an electron injection layer are stacked in this order on the first surfaces of the plurality of first electrodes 121 and the first surface of the insulating layer 13 by, for example, a vapor deposition method, to form the OLED layer 122.

Next, the second electrode 123 is formed on the first surface of the OLED layer 122 by, for example, a vapor deposition method or a sputtering method. The plurality of light-emitting elements 12 is thus formed on the first surface of the drive substrate 11.

Next, the first protective layer 141 is formed on the first surface of the second electrode 123 by, for example, a CVD method or a vapor deposition method. Next, the first metal oxide layer 142 is formed on the first surface of the first protective layer 141 by, for example, atomic layer deposition (ALD). Next, the second protective layer 143 is formed on the first surface of the first metal oxide layer 142 by, for example, a CVD method or a vapor deposition method. Next, the second metal oxide layer 144 is formed on the first surface of the second protective layer 143 by, for example, ALD. The multilayer body 14 is thus formed on the first surface of the second electrode 123.

Next, as illustrated in FIG. 5B, the second metal oxide layer 144 is patterned by, for example, a photolithography technique and a dry etching technique, and the openings 144a are formed in the second metal oxide layer 144 around the light-emitting elements 12 in plan view. Next, as illustrated in FIG. 5C, the second protective layer 143 is etched, using the second metal oxide layer 144 as a mask, in a self-aligned manner to form the grooves 14a. At this time, the second protective layer 143 is etched to a position of the first surface of the second metal oxide layer 144.

Next, a resin such as an ultraviolet curable resin is applied onto the first surface of the second metal oxide layer 144 by, for example, a spin coating method and the grooves 14a are filled with a resin such as an ultraviolet curable resin, and then the resin is cured by, for example, ultraviolet irradiation or the like to form the resin layer 15. Next, the red filter portions 16FR, the green filter portions 16FG, and the blue filter portions 16FB are formed on the first surface of the resin layer 15 by, for example, a photolithography technique, a dry etching technique, or the like. As a result, the color filter 16 is obtained.

Next, the lenses 17a are formed on the first surfaces of the red filter portions 16FR, the green filter portions 16FG, and the blue filter portions 16FB by, for example, a photolithography technique, a dry etching technique, or the like. As a result, the lens array 17 is obtained. Next, the lens array 17 is covered with the filling resin layer 18 using, for example, a one drop fill (ODF) method, and then the counter substrate 19 is disposed on the filling resin layer 18. Next, by applying heat to the filling resin layer 18 or irradiating the filling resin layer 18 with ultraviolet rays to cure the filling resin layer 18, for example, the lens array 17 and the counter substrate 19 are bonded together via the filling resin layer 18. As a result, the display device 10 is sealed. The display device 10 illustrated in FIG. 2 is thus obtained.

### [Actions and Effects]

As described above, the display device 10 according to an embodiment includes the multilayer body 14 having a groove 14a around each light-emitting element 12 in plan view and the resin layer 15 provided on the first surface of the multilayer body 14 in such a way as to fill the grooves 14a. The grooves 14a are provided over the second metal oxide layer 144 and the second protective layer 143, and the refractive index of the resin layer 15 is lower than that of the second protective layer 143. As a result, as illustrated in FIG. 4, the light 12L emitted from the light-emitting elements 12 in an oblique direction with respect to the first surface of the drive substrate 11 can be refracted by the side surfaces 14S of the grooves 14a and directed to the front surface of the display device 10. The light 12L emitted from the light-emitting elements 12, therefore, can be guided to the front of the display device 10. As a result, the luminance in the front surface direction and the light extraction efficiency can be improved.

In the display device 10 according to one embodiment, the luminance in the front surface direction and the light extraction efficiency can be improved without providing a reflector structure described in Patent Document 1. It is therefore possible to improve the luminance in the front surface direction and the light extraction efficiency while inhibiting deterioration (for example, occurrence of luminance unevenness in peripheral portions of the light-emitting elements 12 due to leakage current and the like) of characteristics of the display device due to changes in thickness of the OLED layer 122.

It is also possible to reduce power consumption of the display device 10 by improving the luminance in the front surface direction and the light extraction efficiency.

A waveguide structure of the grooves 14a has high affinity with members such as the curved first electrodes 121 (refer to a first modification) and the lens array 17, and can be easily combined with other members. A degree of freedom in design, therefore, can be improved.

The luminance in the front surface direction can be adjusted by a combination of the waveguide structure of the grooves 14a and the lens array 17. A degree of freedom in design, therefore, can be improved.

### 2 Modifications

### [First Modification]

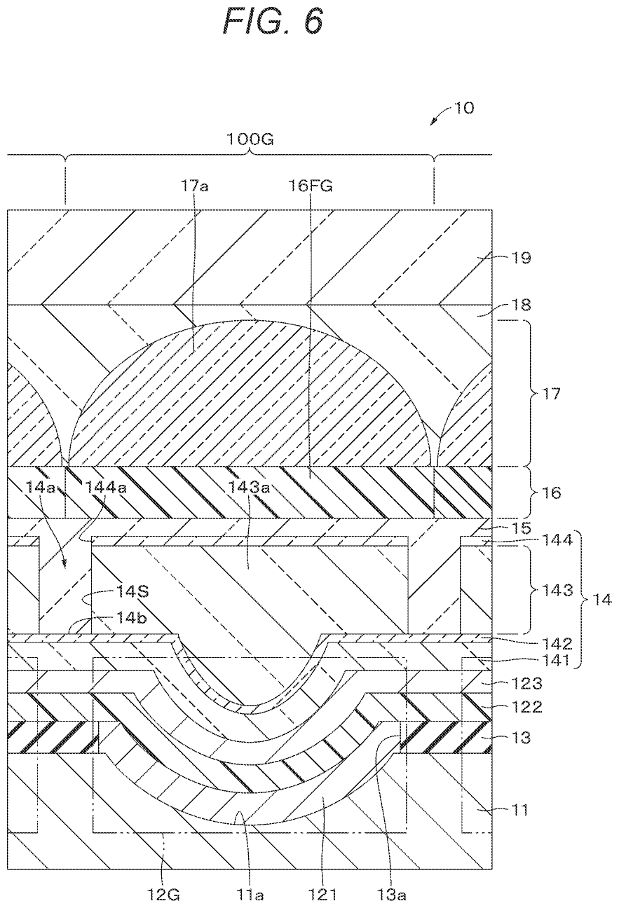

Although an example in which the first surface of the drive substrate 11 is planar has been described in the above embodiment, the drive substrate 11 may have a plurality of recesses 11a in the first surface, instead, as illustrated in FIG. 6. The recesses 11a have concave curved surfaces recessed in a direction away from the display surface. The curved surfaces have, for example, a dome shape, a paraboloid shape, a hemispherical shape, a semi-ellipsoidal shape, or the like. The plurality of recesses 11a is provided at positions where the light-emitting elements 12 are provided. The light-emitting elements 12 are formed in such a way as to follow the curved surfaces of the recesses 11a. More specifically, the first electrodes 121, the OLED layer 122, and the second electrode 123 are formed in such a way as to follow the curved surface of the recesses 11a.

Since the light-emitting elements 12 are formed in such a way as to follow the curved surfaces of the recesses 11a as described above, the first electrodes 121 included in the light-emitting elements 12 are curved in a concave shape. As a result, since light emitted from the OLED layer 122 is reflected by the first electrodes 121, which are curved in a concave shape, toward the front direction, the light extraction efficiency can be further improved.

The drive substrate 11 may include the recesses 11a at positions where one or two particular types of light-emitting elements 12 among the light-emitting elements 12R, 12G, and 12B. In this case, light extraction efficiency of particular one or two types of sub-pixels 100 among the sub-pixels 100R, 100G, and 100B can be improved.

### [Second Modification]

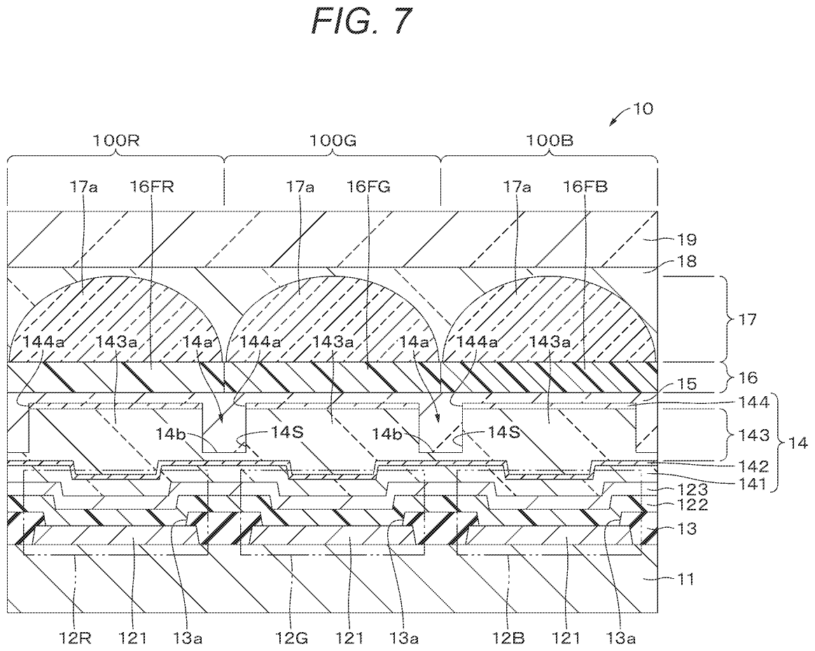

Although an example in which the grooves 14a are provided down to the position of the first surface of the first metal oxide layer 142 has been described in the above embodiment, the grooves 14a may be provided down to a position shallower than the first surface of the first metal oxide layer 142, instead, as illustrated in FIG. 7. That is, the material of the second protective layer 143 may remain in the bottoms 14b of the grooves 14a.

### [Third Modification]

Although an example in which the grooves 14a each have a closed loop shape in plan view and surround one of the light-emitting elements 12 in plan view has been described in the above embodiment, the grooves 14a may each be provided in part of the periphery of one of the light-emitting elements 12 in plan view. For example, the grooves 14a may each be provided in a part of the periphery of one of the light-emitting elements 12 in a horizontal direction, a part of the periphery of one of the light-emitting elements 12 in a vertical direction, or parts of the periphery of one of the light-emitting elements 12 in both the horizontal direction and the vertical direction. Positions at which the grooves 14a are provided with respect to the light-emitting elements 12 may be different depending on a position in the display region 110a.

### [Fourth Modification]

Although an example in which the sub-pixels 100R, 100G, and 100B have a quadrangular shape in plan view has been described in the above embodiment, the sub-pixels 100R, 100G, and 100B may have a hexagonal shape, a circular shape, an elliptical shape, or the like in plan view, instead.

### [Fifth Modification]

The display device 10 may have a resonator structure. The resonator structure may be achieved by the first electrodes 121 and the second electrode 123. The display device 10 may include a semi-transmission reflection layer provided above the second electrode 123, and the semi-transmission reflection layer and the first electrodes 121 may together achieve a resonator structure, instead. The display device 10 may include a reflection layer provided below the first electrodes 121, and the reflection layer and the second electrodes 123 may together achieve a resonator structure, instead. In this case, transparent electrodes are used as the first electrodes 121.

### [Sixth Modification]

Although an example in which the OLED layer 122 can emit white light and is shared by the plurality of sub-pixels 100 in the display region 110a has been described, the configuration of the OLED layer of the display device 10 is not limited to this example. For example, the display device 10 may include a plurality of OLED layers, and the OLED layers may each be provided for one of the sub-pixels 100. In this case, the sub-pixels 100R may include a red OLED layer capable of emitting red light, the sub-pixels 100G may include a green OLED layer capable of emitting green light, and the sub-pixels 100B may include a blue OLED layer capable of emitting blue light.

### [Other Modifications]

Although an embodiment of the present disclosure and modifications thereof have been specifically described above, the present disclosure is not limited to the above-described embodiment and the modifications thereof, and various modifications based on the technical idea of the present disclosure can be made.

For example, the configurations, the methods, the steps, the shapes, the materials, the numerical values, and the like described in the above-described embodiment and the modifications thereof are merely examples, and other configurations, methods, steps, shapes, materials, numerical values, and the like may be used as necessary.

For example, the configurations, the methods, the steps, the shapes, the materials, the numerical values, and the like in the above-described embodiment and the modifications thereof can be combined with each other without departing from the gist of the present disclosure.

For example, the materials exemplified in the above-described embodiment and the modifications thereof can be used alone or in combination of two or more unless otherwise specified.

Furthermore, the present disclosure may also employ the following configurations.
(1)

A display device including:
a substrate;
a plurality of light-emitting elements disposed on the substrate;
a multilayer body covering the plurality of light-emitting elements and having a groove around each of the light-emitting elements in plan view; and
a resin material provided in the groove, in which the multilayer body includes a first protective layer, a first metal oxide layer, a second protective layer, and a second metal oxide layer in this order,
the groove is provided over the second metal oxide layer and the second protective layer, and
a refractive index of the resin material is lower than a refractive index of the second protective layer.
(2)

The display device according to (1), in which the groove is provided to a surface of the second metal oxide layer.
(3)

The display device according to (1) or (2), in which the first metal oxide layer and the second metal oxide layer each include a deposited monolayer.
(4)

The display device according to any one of (1) to (3), in which
the first metal oxide layer contains aluminum oxide or titanium oxide, and
the second metal oxide layer contains aluminum oxide or titanium oxide.
(5)

The display device according to any of one (1) to (4), further including:
an insulating layer provided on the substrate and having a plurality of openings, in which
each of the openings is provided for one of the light-emitting elements, and
the groove is provided outside the opening in plan view.
(6)

The display device according to any one of (1) to (5), further including:
a plurality of lenses, in which
each of the lenses is provided above one of the light-emitting elements.
(7)

The display device according to (6), in which an edge portion of the lens is located above the groove.
(8)

The display device according to any one of (1) to (7), in which
the substrate has a plurality of recesses each having a concave curved surface, and
the light-emitting element follows the curved surface.
(9)

The display device according to any one of (1) to (8), in which a side surface of the groove is parallel to a thickness direction of the substrate or inclined with respect to the thickness direction of the substrate.
(10)

The display device according to any one of (1) to (9), in which
the light-emitting element includes a first electrode, an OLED layer, and a second electrode in this order,
a width of the groove is 0.5 μm or greater and 5 μm or smaller,
a depth of the groove is 0.5 μm or greater and 5 μm or smaller, and
a width of the first electrode is 1 μm or greater and 5 μm or smaller.
(11)

The display device according to any one of (1) to (10), in which the groove surrounds the light-emitting element in plan view.
(12)

The display device according to any one of (1) to (11), in which the groove is located in part of a periphery of the light-emitting element in plan view.
(13)

An electronic apparatus including the display device according to any one of (1) to (12).
(14)

A method for manufacturing a display device including:
forming a plurality of light-emitting elements on a substrate;
stacking a first protective layer, a first metal oxide layer, a second protective layer, and a second metal oxide layer on the plurality of light-emitting elements in this order;
forming openings in the second metal oxide layer around the light-emitting elements in plan view;
etching the second protective layer using the second metal oxide layer as a mask and forming grooves; and
filling the grooves with a resin material having a refractive index lower than a refractive index of the second protective layer.
(15)

The method for manufacturing a display device according to (14), in which the first metal oxide layer and the second metal oxide layer are formed by atomic layer deposition.

### 3 Application Examples

### (Electronic Apparatuses)

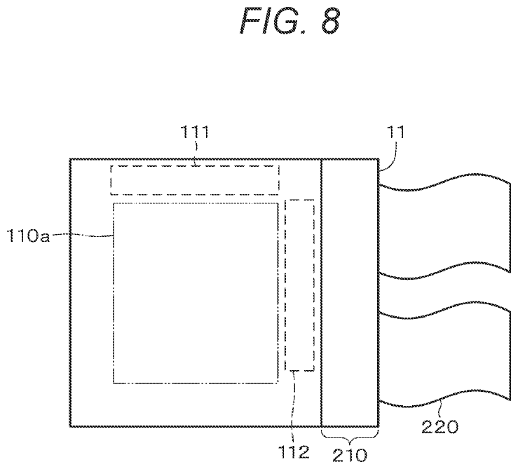

The display devices 10 according to the above-described embodiment and the modifications thereof can be used for various electronic apparatuses. The display device 10 is incorporated into various electronic apparatuses, for example, as a module illustrated in FIG. 8. The module is suitable especially for an electronic viewfinder of a video camera or a single-lens reflex camera, a head-mounted display, or the like where high resolution is required and that are used near the eyes in an enlarged manner. This module has a region 210 exposed without being covered by the counter substrate 19 or the like on one short side of the drive substrate 11, and external connection terminals (not illustrated) are formed in this region 210 by extending wiring of the signal line drive circuit 111 and the scanning line drive circuit 112. A flexible printed circuit (FPC) 220 for inputting and outputting signals may be connected to the external connection terminals.

### Specific Example 1

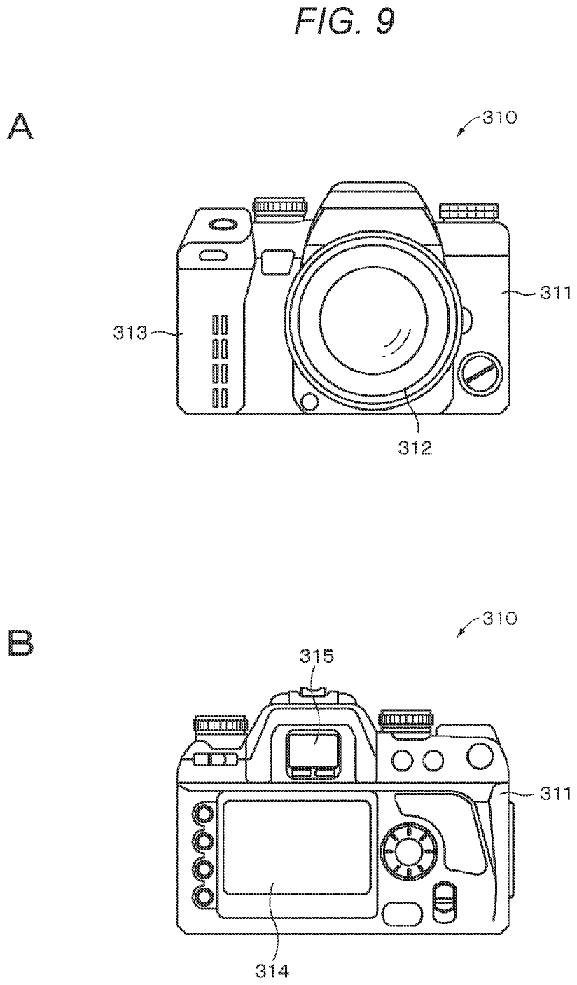

FIGS. 9A and 9B illustrate an example of an external appearance of a digital still camera 310. The digital still camera 310 is of a lens-interchangeable single-lens reflex type, and includes an interchangeable imaging lens unit (interchangeable lens) 312 substantially at the center of a front surface of a camera main body (camera body) 311 and a grip 313 to be held by a photographer on a front left side.

A monitor 314 is provided at a position slightly to the left of the center of a rear surface of the camera main body 311. An electronic viewfinder (eyepiece window) 315 is provided above the monitor 314. By looking through the electronic viewfinder 315, the photographer can visually recognize an optical image of a subject guided from the imaging lens unit 312 and determine a picture composition. The electronic viewfinder 315 includes the display device 10.

### Specific Example 2

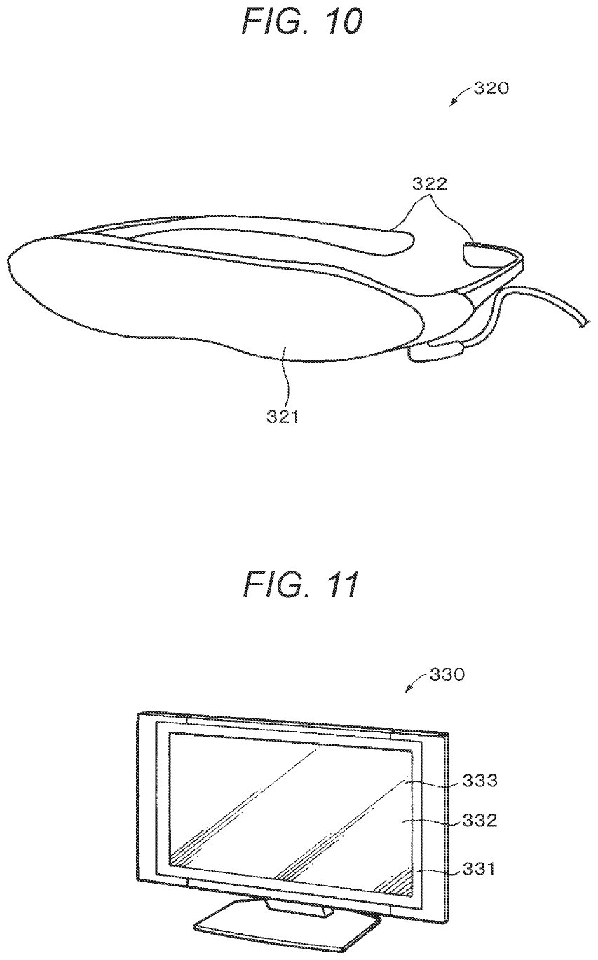

FIG. 10 illustrates an example of an external appearance of a head-mounted display 320. The head-mounted display 320 includes, for example, temples 322 on both sides of a glass-shaped display unit 321 to allow a user to wear the head-mounted display 320 on his/her head. The display unit 321 includes display device 10.

### Specific Example 3

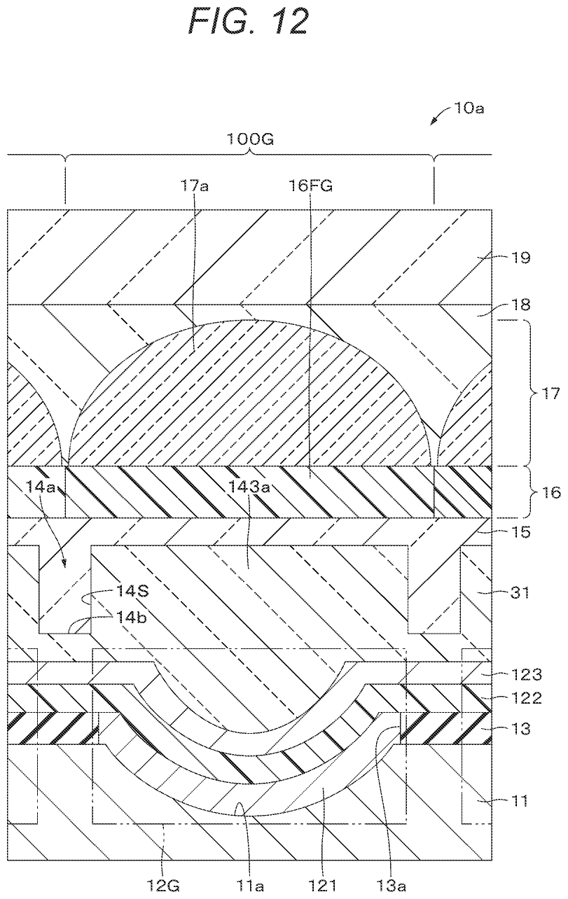

FIG. 11 illustrates an example of an external appearance of a television apparatus 330. The television apparatus 330 includes, for example, a video display screen unit 331 including a front panel 332 and a filter glass 333, and the video display screen unit 331 includes the display device 10.

### 4 Simulations

The present disclosure will be specifically described hereinafter through simulations, but the present disclosure is not limited to these simulations.

### [Simulation 1]

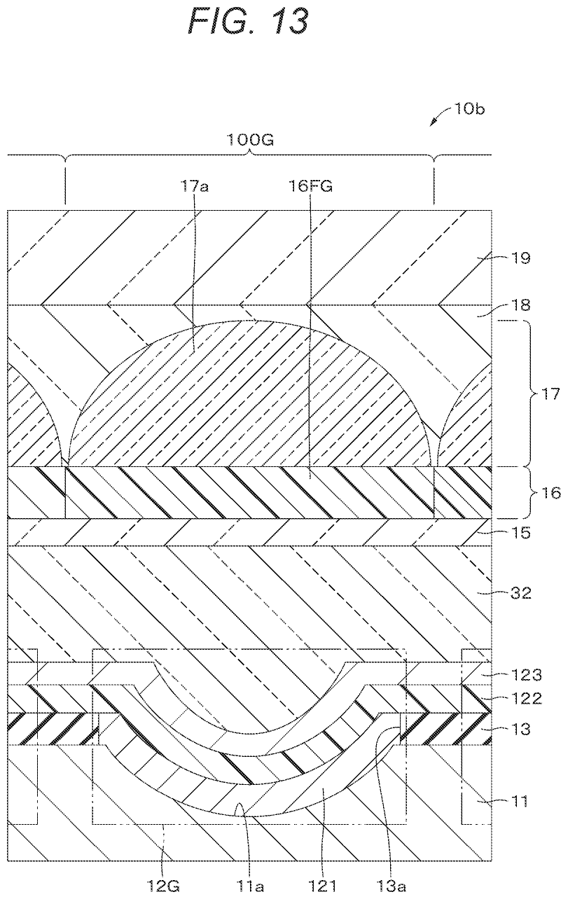

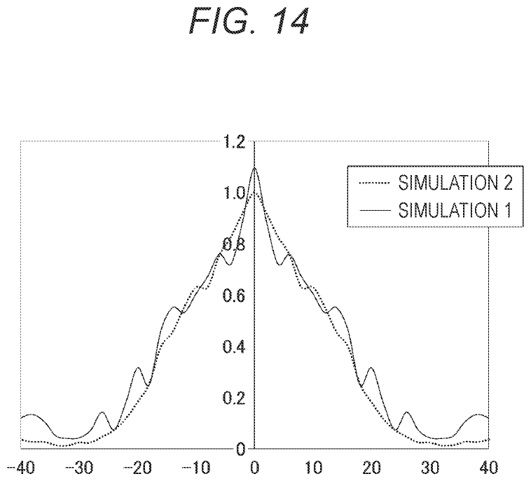

A display device 10a having a configuration illustrated in FIG. 12 was set as a model for simulation 1. The display device 10a was configured similarly to the display device 10 (refer to FIGS. 2 and 4) according to the embodiment except that the second electrode 123 was not provided and a protective layer 31 was provided instead of the multilayer body 14. The protective layer 31 was configured similarly to the multilayer body 14 according to the embodiment except that the first metal oxide layer 142 and the second metal oxide layer 144 were not provided and the first protective layer 141 and the second protective layer 143 used the same material and were integrated together. Luminance of the display device 10a was obtained by simulation. Conditions of the simulation were set as follows. FIG. 14 illustrates a result of simulation 1.

TABLE 1

| | Thickness or | Refractive |
|---|---|---|
| | depth [μm] | index (550 nm) |
| Counter | — | 1.50 |
| substrate 19 | | |
| (glass | | |
| substrate) | | |
| Filling resin | 0.3 | 1.38 |
| layer 18 | | |
| Lenses 17a | 1.9 | 1.56 |
| Color filter | 2.0 | R: 1.68 |
| 16 | | G: 1.62 |
| | | B: 1.53 |
| Resin layer 15 | 0.1 | 1.38 |
| (planarization | | |
| layer) | | |
| Grooves 14a | 0.3 | 1.38 |
| (OCW) | | |
| Protective | 1.0 | 1.70 |
| layer 31 | | |
| OLED layer 122 | 0.1 | 1.80 |
| First | 0.1 | 1.00 |
| electrodes 121 | | |
| Substrate 11 | — | 1.60 |
| (SiO₂) | | |

In Table 1, thickness of the resin layer 15 refers to thickness of the resin layer 15 between an upper surface of the protective layer 31 and the color filter 16. In Table 1, a refractive index refers to a refractive index with respect to light having a wavelength of 550 nm. In Table 1, a refractive index of the grooves 14a refers to a refractive index of the resin material filled in the grooves 14a (that is, the refractive index of the resin layer 15).

### [Simulation 2]

A display device 10b having a configuration illustrated in FIG. 13 was set as a model for simulation 2. The display device 10b was configured similarly to the display device 10a in simulation 1 (see FIG. 12) except that a protective layer 32 was provided instead of the protective layer 31. The protective layer 32 was configured similarly to the protective layer 31 in simulation 1 (see FIG. 12) except that the grooves 14a were not provided. Luminance of the display device 10b was obtained by simulation. FIG. 14 illustrates a result of simulation 2.

It can be seen from FIG. 14 that front surface luminance of the display device 10a (see FIG. 12) provided with the grooves 14a (that is, the waveguide) is higher than that of the display device 10b (see FIG. 13) that is not provided with the grooves 14a.

### REFERENCE SIGNS LIST

10 Display device
11 Drive substrate
12 Light-emitting element
13 Insulating layer
13a Opening
14 Multilayer body
14a Groove
14b Bottom
14S Side surface
15 Resin layer
16 Color filter
16FR Red filter portion
16FG Green filter portion
16FB Blue filter portion
17 Lens array
17a Lens
18 Filling resin layer
19 Counter substrate
31, 32 Protective layer
100R, 100G, 100B Sub-pixel
110a Display region
110b Peripheral region
111 Signal line drive circuit
111a Signal line
112 Scanning line drive circuit
112a Scanning line
121 First electrode
122 OLED layer
123 Second electrode
141 First protective layer
142 First metal oxide layer
143 Second protective layer
144 Second metal oxide layer
310 Digital still camera (electronic apparatus)
320 Head-mounted display (electronic apparatus)
330 Television apparatus (electronic apparatus)

1. A display device comprising:
a substrate;
a plurality of light-emitting elements disposed on the substrate;
a multilayer body covering the plurality of light-emitting elements and having a groove around each of the light-emitting elements in plan view; and
a resin material provided in the groove, wherein
the multilayer body includes a first protective layer, a first metal oxide layer, a second protective layer, and a second metal oxide layer in this order,
the groove is provided over the second metal oxide layer and the second protective layer, and
a refractive index of the resin material is lower than a refractive index of the second protective layer.

2. The display device according to claim 1, wherein the groove is provided to a surface of the second metal oxide layer.

3. The display device according to claim 1, wherein the first metal oxide layer and the second metal oxide layer each include a deposited monolayer.

4. The display device according to claim 1, wherein
the first metal oxide layer contains aluminum oxide or titanium oxide, and
the second metal oxide layer contains aluminum oxide or titanium oxide.

5. The display device according to claim 1, further comprising:
an insulating layer provided on the substrate and having a plurality of openings, wherein
each of the openings is provided for one of the light-emitting elements, and
the groove is provided outside the opening in plan view.

6. The display device according to claim 1, further comprising:
a plurality of lenses, wherein
each of the lenses is provided above one of the light-emitting elements.

7. The display device according to claim 6, wherein an edge portion of the lens is located above the groove.

8. The display device according to claim 1, wherein
the substrate has a plurality of recesses each having a concave curved surface, and
the light-emitting element follows the curved surface.

9. The display device according to claim 1, wherein a side surface of the groove is parallel to a thickness direction of the substrate or inclined with respect to the thickness direction of the substrate.

10. The display device according to claim 1, wherein
the light-emitting element includes a first electrode, an OLED layer, and a second electrode in this order,
a width of the groove is 0.5 μm or greater and 5 μm or smaller,
a depth of the groove is 0.5 μm or greater and 5 μm or smaller, and
a width of the first electrode is 1 μm or greater and 5 μm or smaller.

11. The display device according to claim 1, wherein the groove surrounds the light-emitting element in plan view.

12. The display device according to claim 1, wherein the groove is located in part of a periphery of the light-emitting element in plan view.

13. An electronic apparatus comprising: the display device according to claim 1.

14. A method for manufacturing a display device, the method comprising:
forming a plurality of light-emitting elements on a substrate;
stacking a first protective layer, a first metal oxide layer, a second protective layer, and a second metal oxide layer on the plurality of light-emitting elements in this order;
forming openings in the second metal oxide layer around the light-emitting elements in plan view;
etching the second protective layer using the second metal oxide layer as a mask and forming grooves; and
filling the grooves with a resin material having a refractive index lower than a refractive index of the second protective layer.

15. The method for manufacturing a display device according to claim 14, wherein the first metal oxide layer and the second metal oxide layer are formed by atomic layer deposition.
